(19) United States
(12) Patent Application Publication
(10) Pub. No.: US 2006/0098411 A1
(43) Pub. Date: May 11, 2006

(54) Bendable heat spreader with metallic wire mesh-based microstructure and method for fabricating same

(75) Inventors: Kuo-Ying Lee, Taoyuan Hsien (TW); Chien-Wen Chiu, Hsindian City (TW); Chien-Hung Lin, Taoyuan Hsien (TW); Cherng-Yuh Su, Taipei (TW)

Correspondence Address: BACON & THOMAS, PLLC, 625 SLATERS LANE, FOURTH FLOOR, ALEXANDRIA, VA, 22314, US

(73) Assignee: Taiwan Microloops Corp., Taoyuan Hsien (TW)

(21) Appl. No.: 11/138,478

(22) Filed: May 27, 2005

(30) Foreign Application Priority Data
Nov. 11, 2004 (TW) 093134387

(51) Int. Cl. H05K 7/20

(52) U.S. Cl. 361/704

(57) ABSTRACT

The present invention discloses a heat spreader and method for making the heat spreader. The heat spreader comprises: a hollow metallic housing including an upper cover having an inner surface and a lower cover having an inner surface, the upper and lower covers being bonded together along their perimeters defining a cavity; a capillary structure in a form of metallic meshes bonded to the inner surfaces of the upper and lower covers of the metallic housing; a plurality of reinforcing members disposed in the cavity and bonded between the inner surfaces of the upper and lower covers of the metallic housing; and a working fluid receive in the cavity; wherein bonded surfaces between the metallic meshes and the inner surfaces of the metallic housing, the upper cover and the lower cover, and the reinforcing members and the inner surfaces of the metallic housing all are diffusion-bonded interfaces.

### FIELD OF THE INVENTION

The present invention relates to a heat spreader and method for fabricating same, and more particularly, to a bendable heat spreader with metallic meshes-based microstructure, for example, copper meshes, and method for fabricating same.

### BACKGROUND OF THE INVENTION

Recent electronic appliances such as personal computers, communication devices, TFT-LCD, etc. adopt a variety of electronic devices which generate heat in operation. These devices inevitably generate more heat than before, particularly under the demand of high-speed computation. Therefore, preventing electronic devices from degrading performance due to overheating becomes extremely important, and a variety of cooling devices and methods are developed for this purpose.

For example, a cooler with heat pipe(s) attached to a copper plate has been used in the industry. However, since this kind of heat pipe cannot be used independently, another kind of independent plate type heat pipe, also called a “heat spreader”, has been developed. Due to its ability of allowing independent usage and having good cooling efficiency, the heat spreaders have been widely used in the industry recently.

Generally, the heat spreader is a sealed, hollow housing formed by copper plates. The interior of the housing is evacuated to an extent of vacuum and then filled with a working fluid. A capillary structure is formed on inner walls of the housing. Under vacuum condition, the working fluid absorbs heat from a heat-absorbing side of the housing and vaporizes rapidly. The vaporized working fluid is cooled back to the original liquid phase at a heat-radiating side of the housing where the heat absorbed is radiated out and then the working liquid is directed back to the heat-absorbing side of the housing via the capillary structure to proceed the heat absorbing-radiating cycle repeatedly.

Typically, the capillary structure of a heat spreader can be formed by micro-trench machining or copper-powder sintering. However, it is not so easy to form trenches on a micro scale over the copper plate. In contrast, though copper-powder sintering would be easier for forming the capillary structure, it is difficult to control the final sintering quality, which results in higher scrap rates and thus higher fabrication costs. In addition, in case where bending the heat spreader is needed, the capillary structure formed by copper-powder sintering would be damaged due to the bending.

Moreover, the traditional heat spreader is formed by sealing two half housings into one by, for example, soldering or welding. A known structure of the heat spreader, such as the plate type heat pipe with supports disclosed in Taiwan Utility Model Patent Publication No. 577538, has its supports fixed inside the housing by means of soldering. However, this approach only allows soldering each of the supports at one end while the other end of the supports cannot be soldered after the housing has been sealed. This may result in deformation of the housing due to the heat generated during the soldering operation.

In view of the above mentioned drawbacks, the present invention provides a fabrication method for heat spread that enables the fabrication of heat spreader at lower costs and easier formation of the capillary structure of the heat spreader, and that would less thermally deform the heat spreader housing during the fabricating process. The present invention also provides a heat spreader that can be bended in use and will not easily deform due to absorbing heat.

### SUMMARY OF THE INVENTION

A method for fabricating a heat spreader according to an embodiment of the present invention comprises:
providing an upper cover and a lower cover, each of the covers being a sheet of metallic material and having a perimeter and an inner surface;
attaching metallic meshes to the inner surface of the upper cover and the inner surface of the lower cover using diffusion bonding so as to form a capillary structure on the respective inner surface;
interposing a plurality of reinforcing members between the inner surfaces of the upper cover and the lower cover to which the metallic meshes are attached;
bonding the upper cover, the lower cover and the reinforcing members together using diffusion bonding, such that the inner surfaces of the upper cover and the lower cover define a cavity and the reinforcing members are bonded therebetween;
evacuating the cavity to form a vacuum;
filling a working fluid into the evacuated cavity; and
sealing the cavity with the working fluid therein.

A heat spreader according to an embodiment of the present invention comprises:
a hollow metallic housing including an upper cover having an inner surface and a lower cover having an inner surface, the upper and lower covers being bonded together along their perimeters defining a cavity;
a capillary structure in a form of metallic meshes bonded to the inner surfaces of the upper and lower covers of the metallic housing;
a plurality of reinforcing members disposed in the cavity and bonded between the inner surfaces of the upper and lower covers of the metallic housing; and
a working fluid receive in the cavity;
wherein bonded surfaces between the metallic meshes and the inner surfaces of the metallic housing, the upper cover and the lower cover, and the reinforcing members and the inner surfaces of the metallic housing all are diffusion-bonded interfaces.

According to a preferred embodiment of the present invention, the material forming the metallic housing and reinforcing members is copper or aluminum and the reinforcing members is in the shape of post or strip.

### BRIEF DESCRIPTION OF THE DRAWINGS

Following figures only depict the correlations between elements, not conforming to the proportion of real dimension. In addition, like numerals in the drawings present like elements or features.

FIG. 1 is a perspective view of a heat spreader in accordance with the present invention;

FIG. 2 is a cross sectional view of the heat spreader of FIG. 1 taken on line 2-2 hereof;

FIG. 3 is an exploded perspective view of the spreader of FIG. 2;

FIG. 4 is a cross sectional view of a second embodiment in accordance with a heat spreader of the present invention;

FIG. 5 is an exploded perspective view of the spreader of FIG. 4;

FIG. 6A is a schematic cross sectional view illustrating using a fixture to bond the upper cover and the copper mesh of a heat spreader of the present invention;

FIG. 6B is a schematic cross sectional view illustrating using a fixture to bond the lower cover and the copper mesh of a heat spreader of the present invention;

FIG. 7 is a schematic cross sectional view illustrating use of a fixture to bond the whole heat spreader of FIG. 2;

FIG. 8 is a graph illustrating the profile of temperature and pressure against time for the diffusion bonding of copper upper cover, copper lower cover, copper meshes and copper posts or strips of the heat spreader of the invention;

FIG. 9 is a list of data of the temperature, pressure and time period on which the graph of FIG. 8 is plotted;

FIG. 10 is a graph illustrating the profile of temperature and pressure against time for the diffusion bonding of aluminum upper and lower covers, and copper meshes of the heat spreader of the invention;

FIG. 11 is a list of data of the temperature, pressure and time period on which the graph of FIG. 10 is plotted;

FIG. 12 a graph illustrating the profile of temperature and pressure against time for the diffusion bonding of aluminum upper and lower covers, and aluminum posts or strips of the heat spreader of the invention; and

FIG. 13 is a list of data of the temperature, pressure and time period on which the graph of FIG. 12 is plotted.

### DETAILED DESCRIPTION OF THE PREFERRED EMBODIMENTS

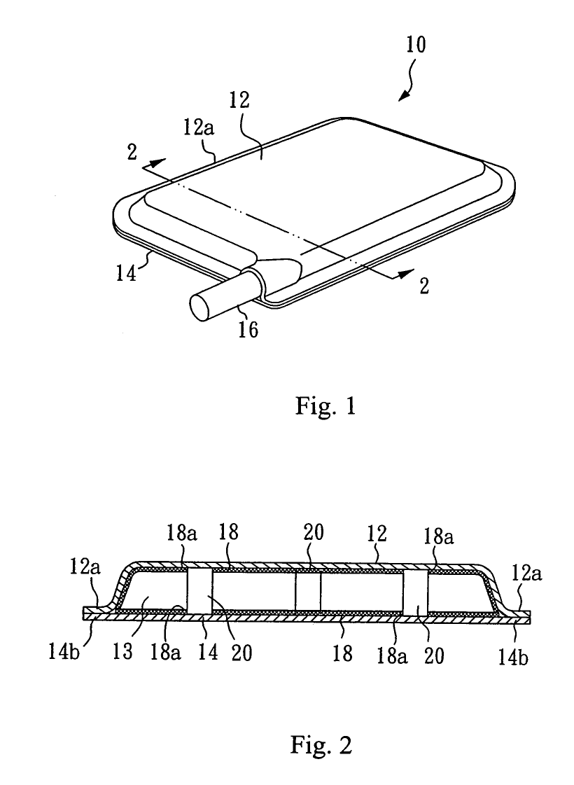

FIG. 1 illustrates a heat spreader 10 in accordance with the present invention. The heat spreader 10 comprises an upper cover 12, a lower cover 14 and a filling pipe 16. The material used for these components generally is copper, while any other metals, such as aluminum, can also be used as long as they having good heat-dissipating capability.

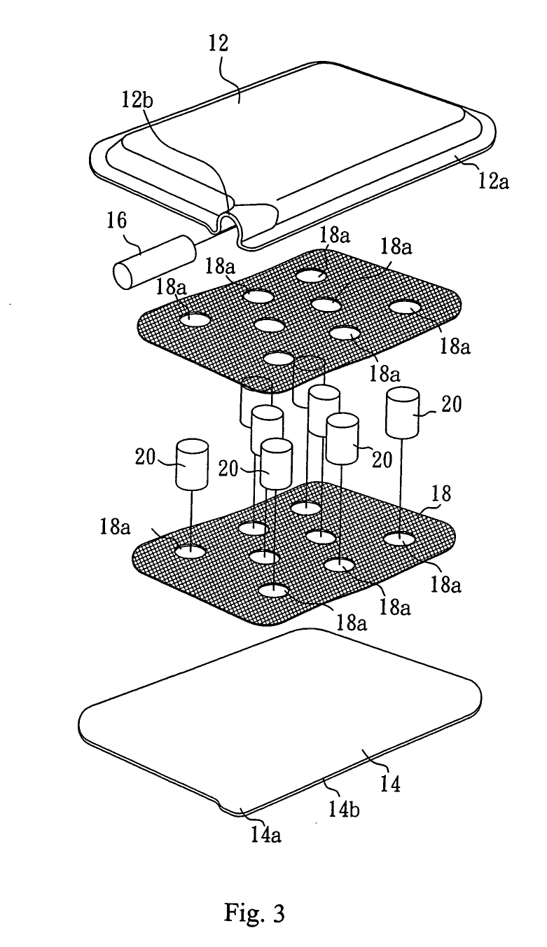

FIGS. 2 and 3 illustrate the heat spreader 10 in accordance with a first embodiment of the present invention. The upper cover 12 and lower cover 14 each have a perimeter 12a, 14b, respectively. A portion within the perimeter 12a of upper cover 12 protrudes slightly. A hermetically sealed cavity 13 is formed by diffusion bonding between the perimeters of the upper cover 12 and lower cover 14. An appropriate volume of working fluid (e.g., pure water, not shown) can be filled in the cavity 13 via the filling pipe 16, one end of which is in fluid communication with the cavity 13, while the other end is sealed after the cavity 13 has been filled with the working fluid.

According to one aspect of the present invention, copper meshes 18 are attached to the inner surface of the heat spreader so as to form a capillary structure. In addition, some openings 18a are formed in the meshes, which allow two ends of copper posts 20 to pass through and to be diffusion bonded between the upper cover 12 and lower cover 14, respectively. These copper posts 20 form a housing-reinforcing structure for the heat spreader to prevent it from deforming as a result of vaporization pressure of the working fluid during absorbing heat.

Note that the contour dimensions of the copper meshes 18 are somewhat smaller than those of the upper cover 12 and lower cover 14 so as to ensure that no part of copper meshes extends into the region where the upper cover 12 and lower cover 14 are bonded together. Copper mesh 18 can be obtained by cutting or stamping a commercially available 200 mesh micro copper mesh. The openings 18a are not necessarily required, while it is preferable to have them in this embodiment in order to advantageously position the copper posts 20 used to reinforce the housing structure. The openings 18a can be stamped out at the same time the copper meshes 18 are stamped out so as to obtain an identical layout of the openings 18a on each piece of copper meshes 18. In this embodiment, there are two pieces of copper meshes 18, one attached to the inner surface of the upper cover 18, the other attached to the inner surface of the lower cover 14; however, the number of the copper meshes is not limited to two, more pieces of copper meshes 18 may be used in a stacked manner as well.

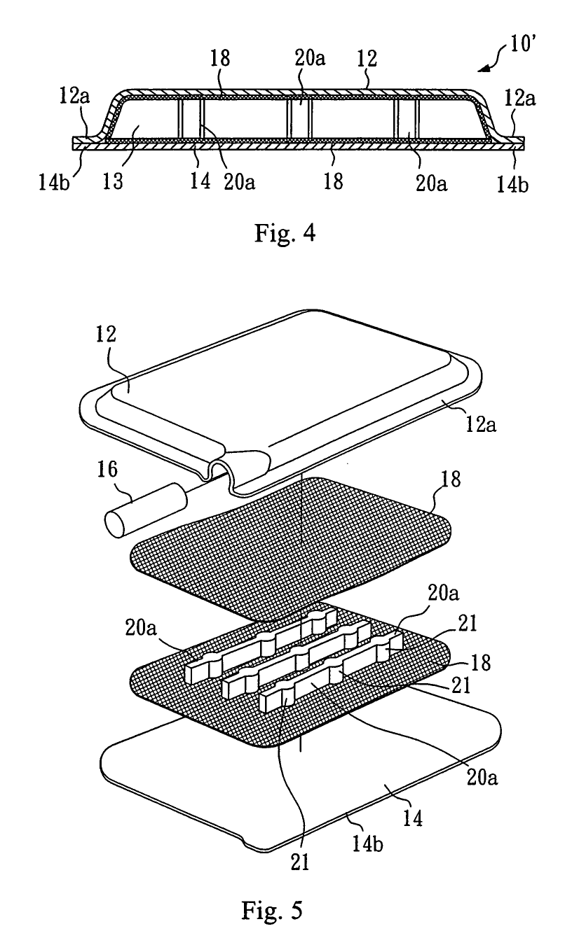

FIGS. 4 and 5 show a heat spreader 10′ in accordance with a second embodiment of the present invention. The major distinction between the first and the second embodiments reside in that the latter employs copper strips 20a as a reinforcing structure in place of the copper posts 20. In this embodiment, copper meshes 18′ do not have openings 18a as in the first embodiment, but openings (not shown) matching the contour of the copper strip 20a can also be made, if desired.

The copper strip 20 is substantially in an elongated shape. In order to more stably place the copper strip 20 and thus facilitate the subsequent bonding operation, a plurality of separated, enlarged portions arranged are formed on the copper strip 20. With these enlarged portions, the copper strip 20 will not easily incline during pre-assembly of the heat spreader. Generally, either copper strip 20a or copper post 20 is used solely, while both of them may be used together, if desired.

It is advantageous that the above-mentioned copper posts or strips may be formed by from sintering copper powders so that fine apertures naturally generated therein by sintering can serve as capillary structure. In addition, it can also be taken into account that capillary structure may be formed by wrapping a copper mesh on a non-sintered copper post or strip (not shown).

A significant advantage of the present invention is that the copper-mesh micro structure, which is used to replace the copper-powder-sintering micro structure, is not only easy to make and cost-effective, but also particularly useful when the heat spreader (10, 10′) is needed to be bended to conform to the contour of a device (heat source) to be cooled or to accommodate itself to other conditions without damaging the micro structure.

Nevertheless, for the internal structure as shown in FIGS. 2 and 3, in order to avoid reducing the integrity of the reinforcing structure of the copper posts 20, it is preferred that the heat spreader is bended at a region where there are no copper posts 20. Therefore, it is possible to arrange the layout of copper posts in advance such that the copper posts can be kept away from the region where the heat spreader is to be bended to conform to the contour of the heat source. However, the reinforcing structure as shown in FIGS. 4 and 5 will not be subject to such limitation, because the elongated copper strip 20a allows the heat spreader 10′ to be bended almost at anywhere without damaging its reinforcing structure.

A method for fabricating the heat spreader 10 in accordance with the first embodiment of the present invention will be described in detail as follows.

Step 1: Forming the Upper Cover and Lower Cover

The upper cover 12 and lower cover 14 can be formed by a sheet of copper material. Typically, there are many processing approaches that may be used, such as stamping, forging or machining, etc. However, for sake of cost consideration, it is preferable to adopt the stamping approach. As shown in FIG. 2, the portion within the perimeter 12a of upper cover 12 is raised by stamping process, while the lower cover 14 is of a flat shape (or of a shape similar to the upper cover 12). The upper cover 12 and lower cover 14 are also stamped, respectively, to form protrusions 12b, 14a (FIG. 3). Then the upper cover 12 and lower cover 14 are washed to eliminate scraps thereon.

Step 2: Attaching the Metallic Meshes onto the Upper Cover and Lower Cover (Diffusion Bonding 1)

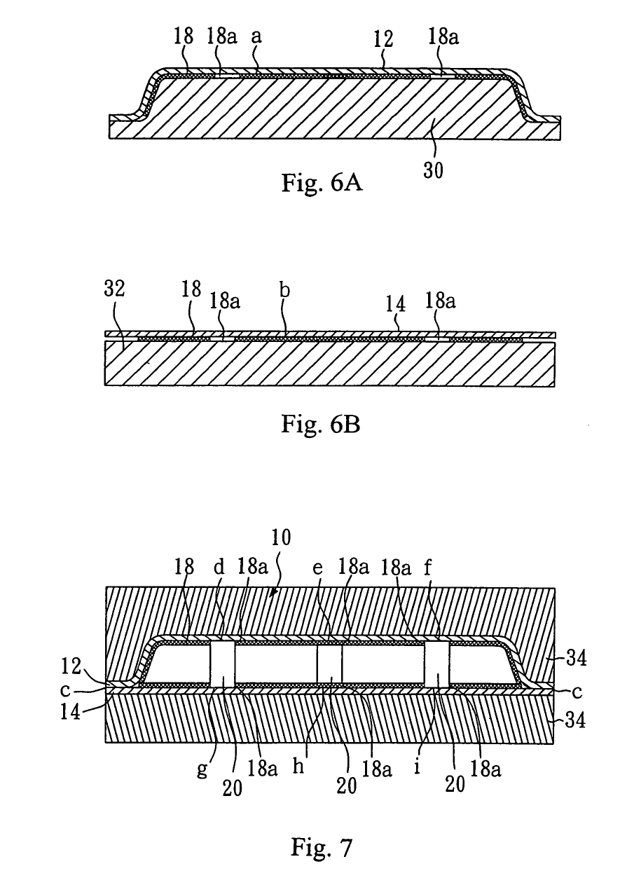

Referring to FIGS. 6A and 6B, one copper mesh 18 is first placed on one bonding fixture 30 (e.g., a tool steel fixture), and then the copper mesh 18 is overlapped by the upper cover 12; another copper mesh 18 is placed on a bonding fixture 32, and then the another copper mesh 18 is overlapped by the lower cover 14. Then the sub-combinations as shown in FIGS. 6A and 6B are sent into a vacuum heat pressing furnace to diffusion bond the copper meshes onto the upper cover and lower cover, respectively.

Diffusion bonding provides bonding between components or materials by properly controlling several bonding parameters such as the temperature, pressure and time duration, such that they can be bonded at a temperature lower than their melting points. For the diffusion bonding of copper material, the temperature and pressure are generally specified as, for example, from 450° C. to 900° C. and from 2 MPa to 20 MPa, respectively, for over 30 minutes (preferably within 3 hours).

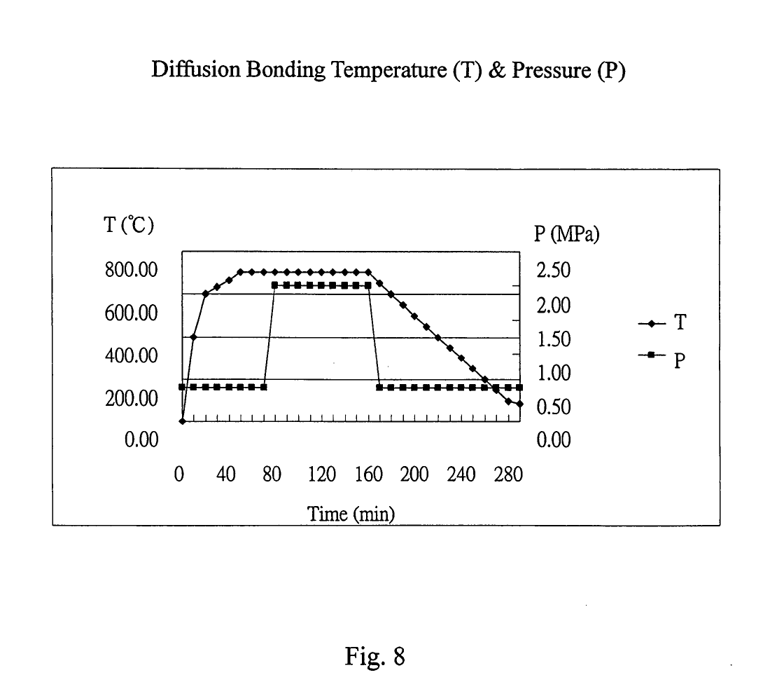

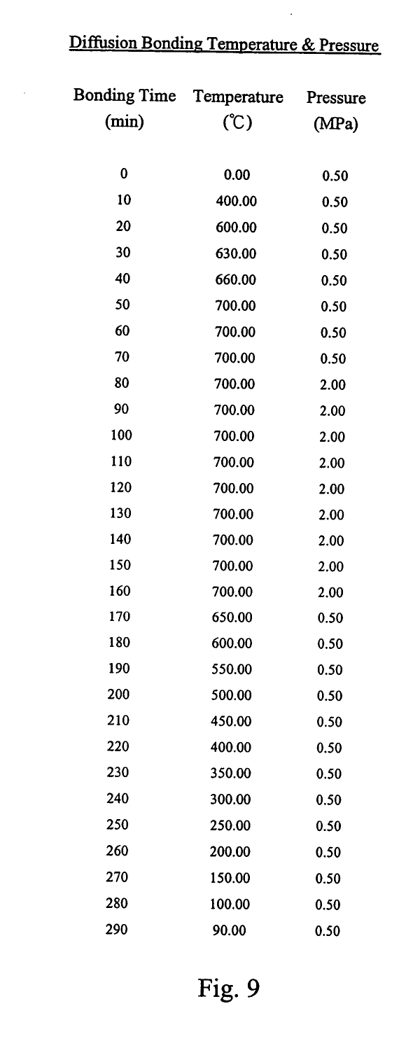

The temperature, pressure and duration for the diffusion bonding specified in the embodiment of the present invention are shown in FIGS. 8 and 9, wherein the diffusion bonding mainly precedes at a temperature of 700° C. and a pressure of 2.0 MPa for about 80 minutes (i.e., from 80^{th} minutes to 160^{th} minutes in the transverse axis).

Now, tow pieces of copper meshes are attached onto the inner surfaces of the upper cover and lower cover, respectively, wherein both the bonded surface a (FIG. 6A) between the copper mesh 18 and the inner surface of the upper cover 12, and the bonded surface b (FIG. 6B) between the copper mesh 18 and the inner surface of the lower cover 14 are diffusion-bonded interfaces.

Step 3: Bonding the Upper Cover Having Copper Mesh, Lower Cover Having Copper Mesh and Reinforcing Posts (Diffusion Bonding 2)

Referring to FIG. 7, the upper cover 12 having copper mesh 18, lower cover 14 having copper mesh 18, and the copper posts 20 are pre-assembled together, such that the upper cover 12 and lower cover 14 are aligned each other and the copper posts 20 are sandwiched therebetween, with two ends of the copper post 20 passing openings 18a to avoid tipping. Then the pre-assembled unit is clamped in a bonding fixture 34, and sent into the vacuum heat pressing furnace again to precede the diffusion bonding process with the same bonding parameters as specified in Step 2.

Now, all of the resulted interface c formed between the upper cover 12 and the lower cover 14, the resulted interfaces d, e, and f formed between the upper cover 12 and the copper posts 20, and the resulted interfaces g, h, and i formed between the lower cover 14 and the copper posts 20 are diffusion-bonded interfaces.

Step 4: Soldering the Pipe

The filling pipe 16 is soldered onto an opening formed by the protrusions 12b, 14a of the upper cover 12 and lower cover 14 (FIG. 1).

Step 5: Testing Pressure and Leakage

The heat spreader 10 is then filled with a testing gas (e.g., nitrogen) to test the pressure resistance and hermetical capability for the structure. If qualified, then the cavity 13 or interior of heat spreader 10 is evacuated to form a vacuum of about between 10⁻³ torr to 10⁻⁷ torr.

Step 6: Filling a Working Fluid

An appropriate volume of a working fluid, for example, pure water, is filled into the cavity 13 of the heat spreader 10 via the filling pipe 16. Other working fluids such as methyl alcohol or coolant, etc., may be used as well.

Step 7: Sealing the Pipe 16

The open end of the pipe 16 is sealed (e.g., by soldering) after the working fluid has been filled.

In the above-described embodiments, copper is used as the material for the upper cover, lower cover, reinforcing structure and capillary structure. However, in a further embodiment for the present invention, aluminum is used in place of copper for the upper cover, lower cover and reinforcing structure, while the capillary structure remains using copper material. In this case, except using another set of bonding parameters due to different material, all of the structure, fabrication method and invention efficacy can refer to the descriptions of the former embodiment. Therefore, the bonding parameters for this embodiment will be further illustrated as bellows.

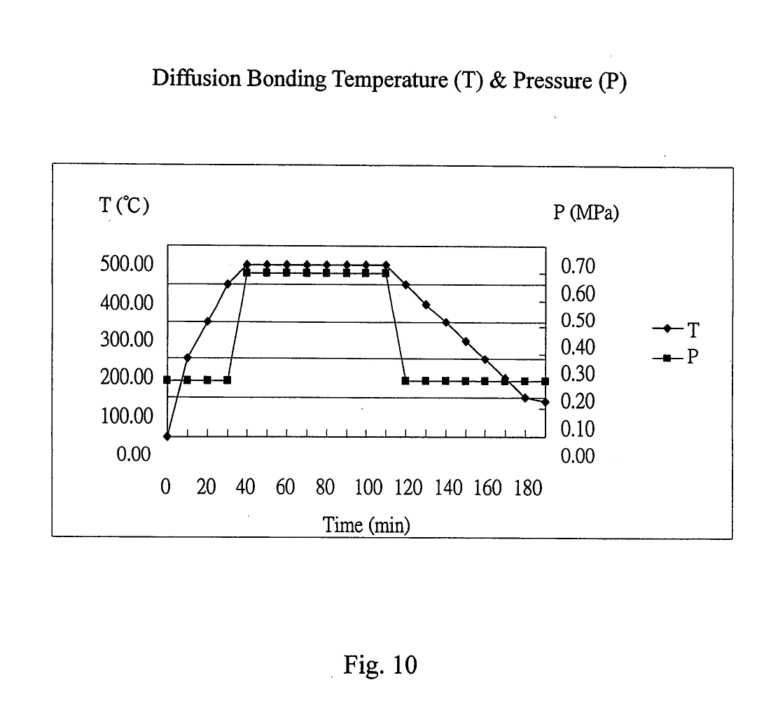

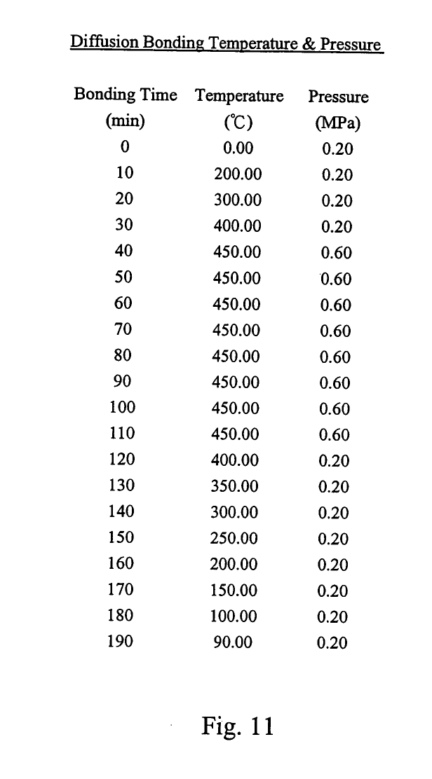

In this embodiment, the first diffusion bonding is directed to the bonding between the aluminum upper cover and lower covers and copper meshes. Generally, the temperature and pressure can be set from 300° C. to 600° C. and from 0.6 MPa to 1.0 MPa, respectively, for about 30 minutes to about 4 hours. The preferred diffusion bonding temperature, pressure and time duration are illustrated in FIGS. 10 and 11. More preferably, the diffusion bonding is carried out at a temperature of about 450° C. and under a pressure of about 0.6 MPa for about 80 minutes.

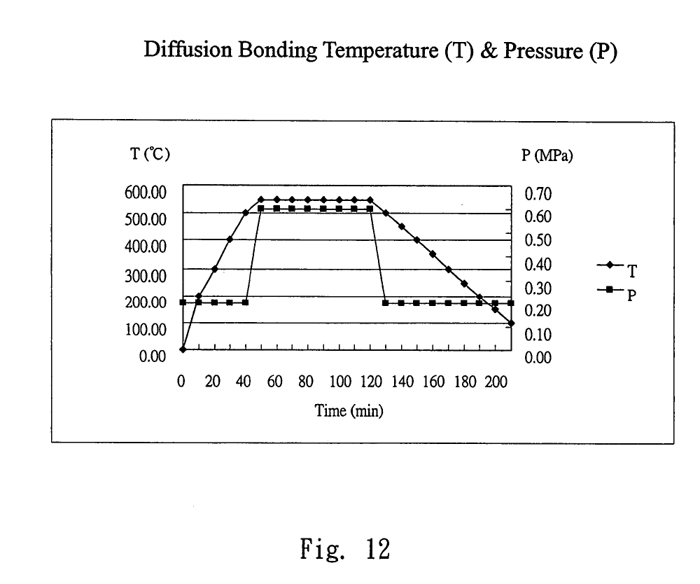

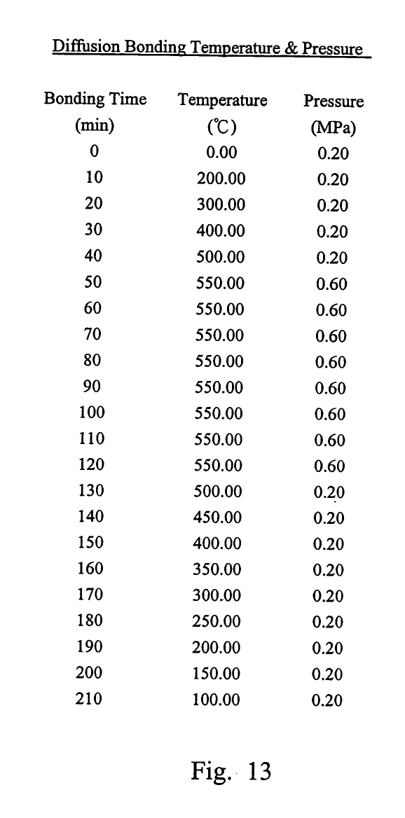

In this embodiment, the second diffusion bonding is directed to the bonding between the aluminum upper and lower covers and the aluminum posts or strips. The preferred diffusion bonding temperature, pressure and time duration are illustrated in FIGS. 12 and 13. More preferably, the diffusion bonding is carried out at a temperature of about 550° C. and under a pressure of about 0.6 MPa for about 80 minutes.

By means of the steps disclosed in the above two embodiments, no matter using copper or aluminum material, a heat spreader having the aforementioned diffusion-bonded interfaces a to i can be obtained. Accordingly, another advantage of the present invention is that because the diffusion-bonded interfaces do not include any foreign interfaces (e.g., solder interfaces), the respective material characteristics of copper and aluminum can be maintained, thereby reducing heat stress and facilitating bending applications for the heat spreader.

While several particular embodiments of the invention have been shown and described, it will be obvious to those skilled in the art that changes and modifications may be made without departing from the invention in its broader aspects and, therefore, the aim in the appended claims is to cover all such changes and modifications and fall within the true spirit and scope of the invention.

We claim:

1. A method for fabricating a heat spreader, comprising:
providing an upper cover and a lower cover, each of the covers being a sheet of metallic material and having a perimeter and an inner surface;
attaching metallic meshes to the inner surface of the upper cover and the inner surface of the lower cover using diffusion bonding so as to form a capillary structure on the respective inner surface;
interposing a plurality of reinforcing members between the inner surfaces of the upper cover and the lower cover to which the metallic meshes are attached;
bonding the upper cover, the lower cover and the reinforcing members together using diffusion bonding, such that the inner surfaces of the upper cover and the lower cover define a cavity and the reinforcing members are bonded therebetween;
evacuating the cavity to form a vacuum;
filling a working fluid into the evacuated cavity; and
sealing the cavity with the working fluid therein.

2. A method according to claim 1, wherein the upper cover, the lower cover and the meshes are made from copper, respectively.

3. A method according to claim 2, wherein the reinforcing members comprise copper posts or copper strips, or a combination thereof.

4. A method according to claim 1, wherein the metallic material for the upper cover and the lower cover is aluminum and the metallic meshes are copper meshes.

5. A method according to claim 4, wherein the reinforcing members comprise aluminum posts or aluminum strips, or a combination thereof.

6. A method according to claim 1, wherein the reinforcing members are bonded between the metallic mesh attached to the upper cover and the metallic mesh attached to the lower cover.

7. A method according to claim 1, wherein each of the metallic meshes has a plurality of openings, and the reinforcing members pass through the openings to connect the inner surfaces of the upper cover and the lower cover.

8. A method according to claim 2, wherein the diffusion bonding is performed at a temperature ranging from 450° C. to 900° C. and under a pressure ranging from 2 MPa to 20 MPa for 30 minutes to 3 hours.

9. A method according to claim 3, wherein the diffusion bonding is performed at a temperature ranging from 450° C. to 900° C. and under a pressure ranging from 2 MPa to 20 MPa for 30 minutes to 3 hours.

10. A method according to claim 8, wherein the diffusion bonding is performed at a temperature of 700° C. and under a pressure of 2.0 MPa for 80 minutes.

11. A method according to claim 4, wherein the diffusion bonding for attaching the copper meshes to the aluminum upper and lower covers is performed at a temperature ranging from 300° C. to 600° C. and under a pressure ranging from 0.6 MPa to 1.0 MPa for 30 minutes to 4 hours.

12. A method according to claim 5, wherein the diffusion bonding for attaching the copper meshes to the aluminum upper and lower covers is performed at a temperature ranging from 300° C. to 600° C. and under a pressure ranging from 0.6 MPa to 1.0 MPa for 30 minutes to 4 hours.

13. A method according to claim 10, wherein the diffusion bonding for attaching the copper meshes to the aluminum upper and lower covers is performed at a temperature of 450° C. and under a pressure of 0.6 MPa for 80 minutes.

14. A method according to claim 10, wherein the diffusion bonding for attaching the aluminum posts or strips to the aluminum upper and lower covers is performed at a temperature of 550° C. and under a pressure of 0.6 MPa for 80 minutes.

15. A heat spreader, comprising:
a hollow metallic housing including an upper cover having an inner surface and a lower cover having an inner surface, the upper and lower covers being bonded together along their perimeters defining a cavity;
a capillary structure in a form of metallic meshes bonded to the inner surfaces of the upper and lower covers of the metallic housing;
a plurality of reinforcing members disposed in the cavity and bonded between the inner surfaces of the upper and lower covers of the metallic housing; and
a working fluid received in the cavity;
wherein bonded surfaces between the metallic meshes and the inner surfaces of the metallic housing, the upper cover and the lower cover, and the reinforcing members and the inner surfaces of the metallic housing all are diffusion-bonded interfaces.

16. A heat spreader according to claim 15, wherein the upper cover, the lower cover and the meshes are made from copper, respectively.

17. A heat spreader according to claim 16, wherein the reinforcing members comprise copper posts or copper strips, or a combination thereof.

18. A heat spreader according to claim 15, wherein the metallic material for the upper cover and the lower cover is aluminum and the metallic meshes are copper meshes.

19. A heat spreader according to claim 18, wherein the reinforcing members comprise aluminum posts or aluminum strips, or a combination thereof.

20. A heat spreader according to claim 15, wherein the reinforcing members are bonded between the metallic mesh of the upper cover and the metallic mesh of the lower cover.

21. A heat spreader according to claim 17, wherein the reinforcing members are bonded between the metallic mesh of the upper cover and the metallic mesh of the lower cover.

22. A heat spreader according to claim 15, wherein each of the metallic meshes further has a plurality of openings, and the reinforcing members pass through the openings to connect the inner surfaces of the upper cover and the lower cover.

23. A heat spreader according to claim 17, wherein each of the metallic meshes further has a plurality of openings, and the reinforcing members pass through the openings to connect the inner surfaces of the upper cover and the lower cover.
